(19) United States
(12) Patent Application Publication
(10) Pub. No.: US 2012/0115088 A1
(43) Pub. Date: May 10, 2012

(54) DEVELOPMENT OF PRINTING MEMBERS HAVING POST-ANODICALLY TREATED SUBSTRATES

(75) Inventors: Kevin Ray, Windham, NH (US); Frederick Richard Kearney, Walpole, MA (US)

(73) Assignee: Presstek, Inc., Greenwich, CT (US)

(21) Appl. No.: 12/943,844

(22) Filed: Nov. 10, 2010

(51) Int. Cl. G03F 7/20; G03F 7/32; G03F 7/40

(52) U.S. Cl. 430/320; 430/435; 430/331

(57) ABSTRACT

Gum solutions are formulated to develop a negative-working photopolymer imaging layer coated on an anodized aluminum substrate that has undergone a post-anodic sealing treatment with inorganic phosphate and inorganic fluoride. The gum solution contains at least one polycarboxylic acid—which may be a polymer—that beneficially desensitizes the surface after the unexposed photopolymer layer is removed.

### BACKGROUND OF THE INVENTION

In offset lithography, a printable image is present on a printing member as a pattern of ink-accepting (oleophilic) and ink-rejecting (oleophobic) surface areas. Once applied to these areas, ink can be efficiently transferred to a recording medium in the imagewise pattern with substantial fidelity. Dry printing systems utilize printing members whose ink-repellent portions are sufficiently phobic to ink as to permit its direct application. In a wet lithographic system, the non-image areas are hydrophilic, and the necessary ink-repellency is provided by an initial application of a dampening fluid or “fountain solution” to the plate prior to inking. The dampening fluid prevents ink from adhering to the non-image areas, but does not affect the oleophilic character of the image areas. Ink applied uniformly to the printing member is transferred to the recording medium only in the imagewise pattern. Typically, the printing member first makes contact with a compliant intermediate surface called a blanket cylinder which, in turn, applies the image to the paper or other recording medium. In typical sheet-fed press systems, the recording medium is pinned to an impression cylinder, which brings it into contact with the blanket cylinder.

Traditional negative-working photopolymer plates include a hydrophilic (typically grained metal) substrate and, thereover, a polymerizable coating. When exposed to actinic radiation the coating crosslinks, hardening and substantially increasing its adhesion to the underlying substrate. Following exposure of the plate to actinic radiation in an imagewise pattern (e.g., by a light source directed through a patterned mask or by laser that scans the plate and is selectively activated in accordance with the image pattern), the plate is subjected to the action of a developer, which removes unexposed portions of the photopolymer coating. These plates are “negative-working” or “direct-write” in the sense that inherently ink-receptive areas receive laser output and persist through development, which reveals the underlying hydrophilic substrate in “background” areas that will reject ink.

Aluminum has been used for many years as a support for lithographic printing plates. In order to prepare the aluminum for such use, it is typically subject to both a graining process and a subsequent anodizing process. The graining process serves to improve the adhesion of the image areas to the plate and to enhance the water-receptive characteristics of the background plate regions. Both mechanical and electrolytic graining processes are well known and widely used in the manufacture of lithographic printing plates. Anodizing creates an anodic oxide coating, which renders the surface hydrophilic and mechanically durable. In order to provide sufficient hydrophilicity for lithographic printing applications, the anodized layer of an aluminum substrate is frequently subjected to any of several post-anodic sealing treatments. The simplest treatment is subjection to hot water. More common post-anodic surface treatments utilize chemicals to, further promote hydrophilicity. These chemicals include sodium silicate, a combination of inorganic phosphate and fluoride salts (usually a monosodium phosphate solution containing sodium fluoride), and treatment with organic polymeric acid (most commonly polymeric phosphonic acids as are well known in the art).

Promotion of hydrophilicity, however, is only one consideration in choosing a surface treatment for the substrate. The crosslinked photopolymer must also have sufficient adhesion in a commercial printing environment to provide adequate plate durability. If the surface of the substrate is too hydrophilic, or does not exhibit sufficient adhesion to the imaging layer after development, the interfacial bond between the ink-receiving layer and the substrate can be weakened by the fountain solution, leading to reduced durability. This problem can be exacerbated by the use of alcohol substitutes, as is, prevalent in the United States. Promoting the hydrophilicity of non-image plate regions for printing purposes, therefore, can come at the expense of ink-transfer performance and overall plate durability. Moreover, not all surface treatments provide sufficient hydrophilicity by themselves. Some treatments, such as those utilizing sodium silicate or polyvinyl phosphonic acid), can provide a sufficiently hydrophilic surface whereas others, such as a phosphate-fluoride treatment, produce a surface that promotes strong adhesion (and consequent plate durability) but are insufficiently hydrophilic in the presence of certain inks and fountain solutions, necessitating chemical treatment in the development stage to prevent the surface from accepting ink. In addition, while phosphate-fluoride treatment provides highly durable surfaces, these come at the price of resistance to development, resulting in the need for aggressive developer chemistries.

Developers for negative-working plates are generally alkaline, typically ranging in pH from 9 to 11. The alkalinity of negative developers is produced by any of several bases, such as sodium silicate or sodium hydroxide, and occasionally by the use of water soluble amines; it may be stabilized by the use of buffers, including phosphates, carbonates, and salts of organic acids. Developers may also contain surfactants to assist in the removal of the non-imaged coating and prevent it from being redeposited on the hydrophilic surface exposed by development. Cosolvents, such as benzyl alcohol or phenoxyethanol, may also be used. However, the pH and solvent content of these developers can make the mixture a hazardous material, which requires special handling and shipping, and expensive waste disposal once the developer is spent. Accordingly, more aggressive developer chemistries come at the price of handling and disposal difficulties and potential environmental toxicity.

Once the hydrophilic surface is exposed by development, it must be protected by contamination from oleophilic dirt and grease in the pressroom environment, which can lead to ink receptivity in background regions. For this reason, a post-development finishing treatment with a “gum solution” is usually performed. This generally requires a separate fluid from the developer in the plate processor.

### SUMMARY OF THE INVENTION

The present invention is directed toward obtaining the durability benefits of phosphate-fluoride surface treatments while mitigating its disadvantages, i.e., lack of adequate hydrophilicity, the need for developers that may be hazardous, and the requirement of a separate gumming step. Developer compositions in accordance herewith offer the safety, economic, and ecological benefits of a non-hazardous developer solution that acts concurrently as a desensitizing protective layer for the hydrophilic surface. Moreover, the developer compositions described herein can serve as gum solutions, obviating the need for a separate gum fluid.

As known in the art, a gum solution is an aqueous liquid that comprises one or more surface-protective compounds capable of protecting the lithographic image of the printing plate against contamination or damage (for example, oxidation, fingerprints, dust or scratches). There are two types of “gum” solutions in common use: (1) a “bake,” “baking,” or “pre-bake” gum usually contains one or more compounds (e.g., one or more anionic surfactants) that do not evaporate at the usual pre-bake temperatures used for making lithographic printing plates; and (2) a “finisher” gum that usually contains one or more hydrophilic polymers (synthetic and/or naturally-occurring, such as gum Arabic cellulosic compounds, (meth)acrylic acid polymers, and polysaccharides) that are useful for providing a protective overcoat on a printing plate. Compositions in accordance herewith may be formulated as “pre-bake” gums, and thus, usually lack the hydrophilic polymers.

Accordingly, in a first aspect, the invention pertains to a method of developing a printing member having a negative-working photopolymer imaging layer on an anodized aluminum substrate, in particular a substrate that has been subjected to (i) a post-anodic sealing treatment of the substrate comprising exposure to an inorganic phosphate and an inorganic fluoride, and (ii) imagewise exposure of the printing member to actinic imaging radiation. The method comprises the step of removing unimaged portions of the photopolymer by applying to the printing member a developer composition comprising water, a surfactant, and a polycarboxylic acid.

In some embodiments, the developer composition further comprises an organic, water-miscible cosolvent which may, for example, be present at a level no greater than 5%. The cosolvent may, for example, be one or more of benzyl alcohol, phenoxyethanol and/or propylene carbonate. The overall pH of the developer composition may range, for example, from 7 to 8.5.

In some embodiments, the printing member is rinsed following the applying step. The method may also include a gumming step of applying a thin layer of the developer composition to the printing member following rinsing; for example, the thin layer after drying may have a deposited weight between 0.1 g/m² and 0.5 g/m².

In various embodiments, the polycarboxylic acid constitutes between 0.05 and 1% of the composition by weight and may be, for example, citric acid.

In another aspect, the invention pertains to a method of printing with a printing member having a negative-working photopolymer imaging layer on an anodized aluminum substrate and which has been subjected to a post-anodic sealing treatment comprising exposure to an inorganic phosphate and an inorganic fluoride. The method comprises imagewise exposing the printing member to actinic imaging radiation and removing unimaged portions of the photopolymer by applying to the printing member a developer composition comprising water, a surfactant, and a polycarboxylic acid.

In still another aspect, the invention relates to a developer composition suitable for developing printing members having a negative-working photopolymer imaging layer on an anodized aluminum substrate. In various embodiments, the composition comprises water, a surfactant, a polycarboxylic acid, and an organic, water-miscible cosolvent present at a level no greater than 5% by weight. The co-solvent may be benzyl alcohol, phenoxyethanol and/or propylene carbonate and the developer composition may have a pH ranging from 7 to 8.5.

In various embodiments, the surfactant is an anionic surfactant, e.g., a salt of an aryl sulfonic acid. The anionic surfactant may be present at a level ranging from 2.5% to 7.5% by volume. The composition may, in various embodiments, also include a defoaming agent. The polycarboxylic acid may be citric acid and, in various embodiments, the polycarboxylic acid may constitute between 0.05 and 1% of the composition by weight.

It should be stressed that, as used herein, the term “plate” or “member” refers to any type of printing member or surface capable of recording an image defined by regions exhibiting differential affinities for ink and/or fountain solution. Suitable configurations include the traditional planar or curved lithographic plates that are mounted on the plate cylinder of a printing press, but can also include seamless cylinders (e.g., the roll surface of a plate cylinder), an endless belt, or other arrangement. The term “substantially” means±10% (e.g., by weight or by volume), and in some embodiments, ±5%. The term “consists essentially of” means excluding other materials that contribute to function. For example, a composition having a surfactant that consists essentially of a salt of an aryl sulfonic acid contains no other material functioning as a surfactant, although it may contain ingredients that do not contribute to this function.

### DETAILED DESCRIPTION

In various embodiments, compositions in accordance with the present invention are gum solutions formulated to develop a negative-working photopolymer imaging layer coated on an anodized aluminum substrate that has undergone a post-anodic sealing treatment with inorganic phosphate and inorganic fluoride (usually a monosodium phosphate solution containing sodium fluoride), hereafter “PF.” The gum solution contains at least one polycarboxylic acid—which may be a polymer—that beneficially (and surprisingly) desensitizes the surface after the unexposed photopolymer layer is removed. The polycarboxylic acid is typically present in amounts sufficient to adjust pH, but in greater than trace amounts: typical levels are between 0.05 and 1%, more preferably between 0.05 and 0.2%. (Percentages given herein are weight percentages unless otherwise indicated.)

In general, a fluid developer in accordance with the invention may be employed either as a single-step developer and protective gum, or used in separate development and gumming stages. The gum solution may be dried in place after development to produce a protective layer. The deposited weight of the gum after drying is typically between 0.1 g/m² and 0.5 g/m², and preferably <0.3 g/m². The gum is preferably a non-hazardous material, which limits its pH to between 3 and 8.5, and more preferably between 7 and 8.5, which generally necessitates the use of buffering salts and acids to retain the pH within this range. The gum may also desensitize the hydrophilic surface against ink receptivity. Various other functional additives, such as defoamers, sequestrants, and biocides may be added to the formulation to improve or ensure performance and longevity in the commercial pressroom.

The gum may additionally contain a surfactant to assist in the removal of unexposed areas of the photopolymer. The surfactant in the gum solution is typically an anionic surfactant, and more preferably a salt of an aryl sulfonic acid. Useful aryl sulfonic acids salts include alkylbenzenesulfonic acid salts, alkylnapthalenesulfonic acid salts, alkyphenoxypolyoxyethylenesulfonic acid salts, alkyldiphenylene oxide disulfonic acid salts, and other salts of chemically similar composition Alkylnaphthalene sulfonic acid salts or alkyldiphenylene oxide disulfonic acid salts offer effectiveness as developers and affordable cost. The anionic surfactant is typically used at 2.5 to 7.5% of the developer composition, preferably at 4 to 6%.

Water-miscible cosolvents known in the art may be used at levels sufficient for promoting removal of unexposed photopolymer, but may be limited to use levels that are acceptable for municipal wastewater streams and which avoid classification of the developer as a hazardous material. In various embodiments, cosolvent levels are less than 5% of the total formulation, but may desirably be less than 1.5%, and more preferably less than 1%. Typical compounds used as cosolvents include benzyl alcohol, phenoxyethanol, glycol ethers such as ethylene glycol butyl ether, n-methylpyrollidone, and derivatives thereof.

Since surfactants used in the formulations described herein have a tendency to promote the production of foam, which can be disruptive when used in a commercial plate processor, a defoaming agent is typically used in the formulation at levels recommended by the manufacturer (typically less than 0.1%). A number of commercially available defoamers can be advantageously used. Other commercially available functional additives, such as biocides, sequestrants, and dyes, may also be included at levels recommended by their manufacturers, and these use levels are also typically on the order of 0.1% or less.

The pH of the developer may be stabilized by a buffer comprising a combination of acidic and basic salts. A number of materials can be used to buffer the pH within the range of 7 to 8.5. A pH of 7 or lower fails to provide sufficient development of the unimaged photopolymer coating, while a pH of 8.5 or more may cause the gum solution to be classified as a hazardous material. Various materials can be used to provide a pH in the desired range, including phosphate salts, carboxylic acid salts, carbonates, and the like. However, it has surprisingly been found that the use of polycarboxylic acids, such as citric acid, is critical for the developer to produce a hydrophilic surface that does not attract ink in the presence of fountain solution. The combination of a PF sealing treatment for optimal adhesion with the use of polycarboxylic acids to provide a sufficiently ink-rejecting hydrophilic surface on the developed substrate is highly advantageous.

Furthermore, it has also surprisingly been discovered that the pH of the developer fluid can limit the ability of the developed surface to reject ink. Developers with a pH of 9.2 or less are capable of producing a cleaned surface that is not ink-receptive in the presence of a fountain solution, yet developers with a pH of 11.35 or greater produce an ink-receptive developed surface. To keep the composition non-hazardous, the preferred pH range is 7 to 8.5.

Developer compositions in accordance herewith can be formulated and mixed in any of various ways. The polycarboxyic acids may be added as a dry powder or a pre-made stock solution, depending on which approach is most expedient or cost effective. Similar considerations may determine the manner of mixing other components of the formulation, such as companion salts for the pH buffer, defoamers, cosolvents, surfactants, and other additives. In general, water is the primary solvent used in the developer compositions. The composition can be mixed by use of an overhead mechanical stirrer with a stir blade, with the components being added in a desired order as long as the amount of water present in the mixture is sufficient to dissolve the component; in general, however, it is convenient to dissolve the buffer salts first, and then the remaining components.

The developer may be applied to the plate surface by hand, but is more typically used in a mechanical processor with at least one tank dedicated to the developer composition and rotary brushes to mechanically scrub and remove non-imaged portions of the exposed plates. Typically, at least one spray bar applies developer fluid, which is recirculated into a reservoir; alternatively, the plate can be immersed in the reservoir. The processor may contain at least one set of rotating scrub brushes that scrub the plate surfaces in the presence of developer, and preferably at least two sets of rotating brushes. An optional rinse stage may be included after the developer stage. A “gumming stage” follows the developer and optional rinse stages; in a typical implementation, gum fluid is sprayed onto the plate surface after development and a squeeze roller is used to meter a thin layer of the gum solution onto the plate, which is then allowed to dry in place. The gum solution may be from the same reservoir as the developer, or a different reservoir; however, both developer gum and finish gum should contain polycarboxylic acids or salts of polycarboxylic acids to desensitize the surface if different fluids are used.

More generally, the gum solution may be applied to the printing member by rubbing, spraying, jetting, dipping, coating, or wiping the outer region with the gum solution or a roller, impregnated pad, or applicator containing the gum solution. For example, the printing member can be brushed with the gum solution, or the gum solution may be poured on or applied by spraying the member with sufficient force to remove the unwanted regions using a spray nozzle system. Still again, the printing member can be immersed in the gum solution and rubbed by hand or with an apparatus.

The gum solution can also be applied in a gumming unit (or gumming station) that has at least one roller for rubbing or brushing the printing member while the gum solution is applied during development. The use of such a gumming unit permits the unexposed regions of the photopolymer layer to be removed from the substrate completely and quickly. Residual gum solution may be removed (for example, using a squeegee or nip rollers) or left on the printing member (and dried) without any rinsing step. The gum solution used in development can be collected in a tank and re-used several times, and replenished as necessary from a reservoir. The gum solution replenisher can be of the same concentration as that used in development, or can be provided in concentrated form and diluted with water at an appropriate time.

Following gumming, the resulting lithographic printing member can be used for printing without any need for a separate rinsing step using water. However, before printing, any excess gum solution may be removed from the lithographic printing member by wiping or use of a squeegee or a pair of nip rollers in an apparatus, followed by optional drying using any suitable drying means.

A post-bake operation can be carried out on the printing member, with or without a blanket or flood-wise exposure to ultraviolet (UV) or visible radiation. Alternatively, a blanket UV or visible radiation exposure can be carried out, without a post-bake operation.

Once the plate has been fully processed, it can be mounted on an offset printing press and used to print several thousand sheets using conventional printing inks and fountain solutions, e.g., up to 100,000 impressions. If the developer is used with a plate that has received a post-anodic treatment other than PF, the developed regions will still repel ink, but the run length may be shorter than that of a plate made with a PF-treated substrate. If a PF-treated plate is rinsed with water instead of being gummed with the developer described herein, or is gummed with a developer that does not contain a polycarboxylic acid, the developed hydrophilic regions may not be sufficiently ink-repelling and instead attract ink, leading to a “toned” background with excessive ink stains on the printed sheet. The combination of PF post-anodic treatment and gum solution developer containing a polycarboxylic acid optimizes run life and a clean printing background.

### EXAMPLES

### Example 1

### Formulation for 5 Nax220-1-Phenoxy-Phos/Citrate Gum Developer Solution

A 5-gallon polyethylene container was charged with 15851.92 g of deionized water, and an overhead stirrer was set up over the container with a 2″ turboprop stirrer inside the tank. The tank was then agitated at 600 rpm. 221.88 g of Na₂HPO₄ and 18.76 g of citric acid were added to the container and allowed to stir 2 hours to mix. 1727.44 g of NAXAN 220 alkylnaphthalene sulfonate surfactant solution (52.1% total solids, Nease Chemical Co.) were added to the stirring buffer solution, followed by 180 g of phenoxyethanol and 13.5 g SURFYNOL DF-62 Defoamer (Air Products), and followed by at least 2 hours additional stirring. The pH of the resulting gum solution was 7.4.

### Example 2

### Formulation for 5 Nax220-0.75Phenoxy-Phos/Citrate Gum Developer Solution

A 5-gallon polyethylene container was charged with 15883.42 g of deionized water, and an overhead stirrer was set up over the container with a 2″ turboprop stirrer inside the tank. The tank was then agitated at 600 rpm. 221.88 g of Na₂HPO₄ and 18.76 g of citric acid were added to the container and allowed to stir 2 hours to mix. 1727.44 g of NAXAN 220 alkylnaphthalene sulfonate surfactant solution (52.1% total solids, Nease. Chemical Co.) were added to the stirring buffer solution, followed by 135 g of phenoxyethanol and 13.5 g SURFYNOL DF-62 Defoamer (Air Products), and followed by at least 2 hours additional stirring. The pH of the resulting gum solution was 7.4.

### Example 3

### Formulation for 5 Nax220-Phos/Bicarbonate Gum Developer Solution

A 5-gallon polyethylene container was charged with 16031.00 g of deionized water, and an overhead stirrer was set up over the container with a 2″ turboprop stirrer inside the tank. The tank was then agitated at 600 rpm. 154.26 g of K₂HPO₄, 73.80 g of NaHCO₃, and 29.52 g of trisodium citrate dihydrate were added to the container and allowed to stir 2 hours to mix. 1727.44 g of NAXAN 220 alkylnaphthalene sulfonate surfactant solution (52.1% total solids, Nease Chemical Co.) were added to the stirring buffer solution, followed by 13.5 g SURFYNOL DF-62 Defoamer (Air Products), and followed by at least 2 hours additional stirring. The pH of the resulting gum solution was 8.6.

### Example 4

### Formulation for 5 Nax220-Phos/Bicarbonate/0.1 Citrate Gum Developer Solution

A 5-gallon polyethylene container was charged with 16031.00 g of deionized water, and an overhead stirrer was set up over the container with a 2″ turboprop stirrer inside the tank. The tank was then agitated at 600 rpm. 154.26 g of K₂HPO₄ and 73.80 g of NaHCO₃ were added to the container and allowed to stir 2 hours to mix. 1727.44 g of NAXAN 220 alkylnaphthalene sulfonate surfactant solution (52.1% total solids, Nease Chemical Co.) were added to the stirring buffer solution, followed by 13.5 g SURFYNOL DF-62 Defoamer (Air Products), and followed by at least 2 hours additional stirring. The pH of the resulting gum solution was 9.02.

### Example 5

### Formulation of Several Developers with Varying pH

The procedures used in the previous examples were applied to the developers in the following table. In general, inorganic salts were dissolved in water first, followed by the addition of surfactants and solvents, with the solvent being added last. The salts were allowed to totally dissolve before adding any further components. The pH of the gum solutions was measured with a pH electrode.

Weight % in solution

| | | | 5Nax220- |
|---|---|---|---|
| | | | 1Ph- |
| | 5Nax220- | 5Nax220- | di/tribasic |
| | 1Ph- | 1Ph-phos/ | Phos- |
| Reagent | phos/citrate | NaCitrate | NaCitrate |
| Naxan 220 | 5 | 5 | 5 |
| phenoxyethanol | 1 | 1 | 1 |
| Na₂HPO₄ | 1.23 | 1.23 | 0.65 |
| Na₃PO₄•12 H₂O | 0 | 0 | 1.75 |
| citric acid | 0.104 | | |
| trisodium citrate | | 0.159 | 0.159 |
| pH | 7.43 | 9.18 | 11.35 |

### Example 6

### Formulation NPCB-1 Gum Developer Solution

A 5-gallon polyethylene container was charged with 15865.42 g of deionized water, and an overhead stirrer was set up over the container with a 2″ turboprop stirrer inside the tank. The tank was then agitated at 600 rpm. 221.88 g of Na₂HPO₄ and 18.76 g of citric acid were added to the container and allowed to stir 2 hours to mix. 1727.44 g of NAXAN 220 alkylnaphthalene sulfonate surfactant solution (52.1% total solids, Nease Chemical Co.) were added to the stirring buffer solution, followed by 135 g of phenoxyethanol, 13.5 g SURFYNOL DF-62 Defoamer (Air Products), and 18 g of PROXEL BD-20 biostat, followed by at least 2 hours additional stirring.

### Example 7

### Formulation NPCB-2 Gum Developer Solution

A 5-gallon polyethylene container was charged with 15696.58 g of deionized water, and an overhead stirrer was set up over the container with a 2″ turboprop stirrer inside the tank. The tank was then agitated at 600 rpm. 221.88 g of Na₂HPO₄ and 187.6 g of a 10% solution of ITACONIX DSP2K (polyitaconic acid, Itaconix Inc.) were added to the container and allowed to stir 2 hours to mix. 1727.44 g of NAXAN 220 alkylnaphthalene sulfonate surfactant solution (52.1% total solids, Nease. Chemical Co.) were added to the stirring buffer solution, followed by 135 g of phenoxyethanol, 13.5 g SURFYNOL DF-62 Defoamer (Air Products), and 18 g of PROXEL BD-20 biostat, followed by at least 2 hours additional stirring.

### Example 8

### Formulation NPCB-3 Gum Developer Solution

A 5-gallon polyethylene container was charged with 15696.58 g of deionized water, and an overhead stirrer was set up over the container with a 2″ turboprop stirrer inside the tank. The tank was then agitated at 600 rpm. 221.88 g of Na₂HPO₄ and 187.6 g of a 10% solution of ITACONIX DSP5K (polyitaconic acid, Itaconix Inc.) were added to the container and allowed to stir 2 hours to mix. 1727.44 g of NAXAN 220 alkylnaphthalene sulfonate surfactant solution (52.1% total solids, Nease Chemical Co.) were added to the stirring buffer solution, followed by 135 g of phenoxyethanol, 13.5 g SURFYNOL DF-62 Defoamer (Air Products), and 18 g of PROXEL BD-20 biostat, followed by at least 2 hours additional stirring.

### Example 9

### Imaging and Development of a Negative-Working Plate with 5 Nax220-1 Phenoxy-Phos/Citrate Gum Solution

An NP-1 formulation, containing a negative-working image layer from My Lan chemicals, was coated on an aluminum substrate with a silicate sealing treatment. This plate was imaged on a TRENDSETTER 3244 (Eastman Kodak) at 5 to 15 W with a drum speed of 120 rpm. The plate was developed with 5 Nax220-1phenoxy-phos/citrate gum solution, using a nonwoven cotton cloth and applying light rubbing pressure before rinsing with deionized water and drying at 91° C. for 43 seconds. This plate was tested for printing performance on a Heidelberg GTO press using Crystal 2500 fountain solution with JETWET alcohol substitute, and black process ink. A good image was obtained above an exposure of 7 W, and the image ran 10,000 impressions, with significant and unacceptable wear in the highlight features.

### Example 10

### Imaging and Machine Development of a Negative-Working Plate with 5 Nax220-1 Phenoxy-Phos/Citrate Gum Solution, Aluminum Substrate with Silicate Sealing

An 18 kg batch of 5 Nax220-1 phenoxy-phos/citrate developer was added to the developer tank of a two-brush ANTHEM Water Wash plate processor (Presstek Inc, Hudson, N.H.), and deionized water was used to fill the rinse tank. An NP-1 formulation, containing a negative-working image layer from My Lan chemicals, was coated on an aluminum substrate with a silicate sealing treatment. This plate was imaged on a TRENDSETTER 3244 (Eastman Kodak) at 14 W with a drum speed of 135 rpm. The plate was developed with 5 Nax220-1 phenoxy-phos/citrate gum solution in the ANTHEM Water Wash processor at 3.2 feet per minute (1.63 cm/second), and allowed to air dry. This plate was tested for printing performance on a SAKURAI OLIVER 72 press using CRYSTAL 2500 fountain solution with JETWET alcohol substitute, and Van Son process black ink. The plate ran for 10,000 impressions, at which point it showed significant wear in the highlight dots and thin line features.

### Example 11

### Imaging and Machine Development of a Negative-Working Plate with 5 Nax220-0.75 Phenoxy-Phos/Citrate Gum Solution, Aluminum Substrate with PF Sealing

An 18 kg batch of 5 Nax220-0.75-Phenoxy-phos/citrate developer was added to the developer tank of a 2-brush ANTHEM Water Wash plate processor, and deionized water was used to fill the rinse tank. An NP-1 formulation, containing a negative-working layer from My Lan chemicals, was coated on an aluminum substrate with a PF sealing treatment. This plate was imaged on an Eastman Kodak TRENDSETTER 3244 at 14 W with a drum speed of 135 rpm. The plate was developed in the ANTHEM Water Wash processor at 3.2 feet per minute (1.63 cm/second), and allowed to air dry. This plate was tested for printing performance on a Heidelberg GTO press using CRYSTAL 2500 fountain solution with JETWET alcohol substitute, and black process ink. The plate rolled up clean from the start and ran with good screen tints for 20,000 impressions, with 3% dots lasting 15,000 impressions and retention of fine features to 20,000 impressions, a significant improvement over the same formulation on silicate-sealed aluminum.

### Example 12

### Imaging, Machine Development, and Gumming of a Negative-Working Plate with 5 Nax220-0.75 Phenoxy-Phos/Citrate Gum Solution, Aluminum Substrate With PF Sealing

18 kg batches of 5 Nax220-0.75 phenoxy-phos/citrate developer were added to the developer and rinse tanks of a 2-brush ANTHEM Water Wash plate processor. An NP-1 formulation, containing a negative-working image layer from My Lan chemicals, was coated on an aluminum substrate with a PF sealing treatment. This plate was imaged on a TRENDSETTER 3244 at 14 W with a drum speed of 135 rpm. The plate was developed with 5 Nax220-0.75 phenoxy-phos/citrate gum solution in the ANTHEM Water Wash processor at 3.2 feet per minute (1.63 cm/second), and allowed to air dry. This process yields a developed plate with a protective layer of gum solids. This plate was tested for printing performance on a Heidelberg GTO press using CRYSTAL 2500 fountain solution with JETWET alcohol substitute, and black process ink. The plate rolled up clean from the start and ran with good screen tints and 3% highlight dots for 40,000 impressions, which is an acceptable run length.

The previous four examples demonstrate the ability of developer compositions in accordance herewith to effectively develop negative-working plates; the ability to use the same fluid as a finishing gum solution; and the increased adhesion and run length obtained when PF sealed anodized aluminum is used instead of silicate-sealed anodized aluminum.

### Example 13

### Comparison of Aluminum Substrates with Silicate Vs. PF Sealing Treatment, Processed with Various Developer Compositions

Anodized aluminum substrates subjected to various scaling treatments were run through the ANTHEM Water Washer at 3.2 feet per minute (1.63 cm/second), with various combinations of fluids in the developer and rinse tanks as shown in the table below. The plates treated in this manner were rolled up on a Heidelberg GTO press, using process black ink and CRYSTAL 2500 fountain solution and JETWET alcohol substitute, for a maximum of 200 impressions to evaluate the fountain receptivity and ink rejection of the developed substrate. The ink take results are shown in the last column of the following table. AEON Finisher Gum is a positive-plate gum supplied by Presstek Inc., and which contains trisodium citrate and citric acid.

| Sealing | | | |
|---|---|---|---|
| Treatment | Developer | Rinse | Roll up |
| None | none | none | rolled up solid |
| Silicate | none | none | Clean from start |
| PF | none | none | rolled up solid |
| PF | 5% Nax200 - | Aeon | Clean from start |
| | KPhosphate/bicarbonate/ | Finisher Gum | |
| | 0.1% NaCitrate | | |
| PF | 5% Nax200 - | water | Clean from start |
| | KPhosphate/bicarbonate/ | | |
| | 0.1% NaCitrate | | |
| PF | 5% Nax200 - | Aeon | Clean from start |
| | KPhosphate/bicarbonate | Finisher Gum | |
| PF | 5% Nax200 - | water | Toned from start, |
| | KPhosphate/bicarbonate | | dirty to 200′ |

The results show that the presence of citrate ion or citric acid is critical in at least the developer stage when PF substrate is used: developers without citrate ion fail to produce an ink-rejecting surface, while developers with citrate ion produce a surface that is not toned in the presence of ink and fountain solution. The same effect can be produced by a finishing solution that desensitizes the developed surface, if the developer does not contain citrate ion. Rinsing the plate with water removes most of the developer but may leave traces of developer components, including the citric acid; hence, the clean background on the fifth entry in the table. However, the absence of any citrate in the developer at all, as shown in the last entry, will lead to a plate with an ink-receiving anodic layer similar to the untreated PF substrate. Plates subjected to silicate-sealing treatment do not require citrate ion in either the rinse or developer, but as shown by Examples 9-12, this sealing treatment produces a less durable plate than a substrate with PF sealing treatment.

### Example 14

### Comparison of Development with 5 Nax220-0.75 Phenoxy-Phos/Citrate Developer on a PF Sealed Anodized Aluminum Substrate, with and without a Finishing Gum Post-Treatment

An NP-1 plate was imaged at 14 W/135 rpm in a Trendsetter before processing in an ANTHEM Water Wash processor with 5 Nax220-0.75 phenoxy-phos/citrate solution in the developer tank and water in the rinse tank. One plate thus processed was tested without modification; another was coated afterward with the gum developer solution by wiping it onto the plate surface with a damp cloth and buffing it dry. Both plates were rolled up on the GTO press under the same conditions as in Example 13, with the results shown in the table below.

| Developer | Rinse | Rollup |
|---|---|---|
| 5Nax220-0.75% phenoxy- | water | toning in |
| phosphate/citrate | | places |
| 5Nax220-0.75% phenoxy- | dev. buff on | OK |
| phosphate/citrate | | |

### Example 15

### Comparison of Various Wash/Rinse Combinations of 5 Nax220-0.75-Phenoxy-Phos/Citrate Developer on a PF Sealed Anodized Aluminum Substrate

Anodized aluminum substrates with PF sealing treatments were run through the ANTHEM Water Washer at 3.2 feet per minute (1.63 cm/second), with various combinations of fluids in the developer and rinse tanks as shown in the table below. The plates treated in this manner were rolled up on a Heidelberg GTO press, using process black ink and CRYSTAL 2500 fountain solution and JETWET alcohol substitute, for a maximum of 200 impressions to evaluate the fountain receptivity and ink rejection of the developed substrate. The ink take results are shown in the last column of the following table.

| Dev. Tank | Rinse Tank | Roll up |
|---|---|---|
| none | none | Solid black |
| water | water | heavily toned, got worse through run |
| water | NPCB-1 | started clean, stayed clean |
| water | NPCB-2 | started clean, stayed clean |
| water | NPCB-3 | started clean, stayed clean |

Examples 14 and 15 demonstrate the desirability of leaving the gum solution on the developed plate in order to desensitize it and protect it from the environment. it also shows that several different polyacids are effective in providing desensitization and environmental protection for the developed surface. As shown in the fifth row of the table of Example 13 (and Example 11), rinsing with water after development may leave traces of carboxylic polyacid in the background that can desensitize the developed surface to ink receptivity, but Example 14 shows that the amount of residue left after rinsing is inconsistent and may be insufficient to desensitize the anodized surface. The present example illustrates that the most reliable practice is to let the developer dry in place as a thin protective layer (as in, e.g., Example 12 and Example 17 below).

### Example 16

### Comparison of Various Wash/Rinse Combinations of 3 Developers with Different pH on a Negative Working Plate with a PF Sealing Treatment

An NP-1 plate coated on anodized aluminum substrate with a PF sealing treatment was imaged in the TRENDSETTER 3244 at 14 W/135 rpm. This plate was developed with the three different developers listed in Example 5 by wiping the developer on the plate by hand with a nonwoven cotton cloth. The development was followed by one of two post-treatments: (a) rinsing with DI water and drying in room air, or (b) wiping the developed plate with fresh developer and buffing dry with a dry cloth. Rinsing the plate removes as much gum solution as possible, while buffing the plate dry guarantees a residual coating of the gum solution solids on the plate. The plates were then spliced back together and nm on a GTO press under the same conditions as in previous examples. The action of the developer on the exposed image area and in the non-printing background was observed, with the following results:

| | | | Ink Rejection on press | |
|---|---|---|---|---|
| Developer | | Quality of | | Developer |
| Formulaton | pH | Developed Image | Water Rinse | buff dry |
| 5Nax220- | 7.43 | Good, no damage | moderate | clean |
| 1Ph- | | to imaged coating | toning | background |
| phos/citrate | | | | |
| 5Nax220- | 9.18 | slight damage to | moderate | clean |
| 1Ph-phos/ | | the imaged | toning | background |
| NaCitrate | | coating | | |
| 5Nax220- | 11.35 | severe damage to | rolled | rolled |
| 1Ph- | | the imaged | up solid | up solid |
| di/tribasic | | coating | | |
| Phos- | | | | |
| NaCitrate | | | | |

The development and print results suggest that in order to provide sufficient desensitization and protection of a PF-sealed anodized aluminum surface, the citrate-containing gum should be left on the plate as a protective layer. However, there are, also pH effects that are independent of the presence of citrate ion in the gum solution. Increasing the alkalinity of the developer above a pH of ˜9.0 can damage the image layer either by digestion of the coating or loss of adhesion; furthermore, increasing the alkalinity of the developer too far actually leads to re-sensitization of the surface and undesirable ink receptivity in the developed surface.

### Example 17

### Use of a Gum Solution Developer in a Single-Stage Gum/Processing Unit

18 kg of 5 Nax220-0.75 phenoxy-phos/citrate from Example 2 was loaded into the reservoir of an Agfa C85 single-stage processor. The developer fluid in this processor is applied with a spray bar with a subsequent 10-second dwell, followed by cleaning with two scrub brushes, and subsequently followed by rinsing with the same gum fluid, running the wet plate through a squeeze roller, and drying with warm air. The developer gum is applied to the surface as a protective coating as the last stage in this processor. An NP-1 plate was exposed in the Eastman Kodak TRENDSETTER 3255 at 14 W/135 rpm, and was processed in the C85 processor with the gum solution. The unexposed areas of the plate coating were fully removed, while retaining a good exposed image.

### Example 18

### Formulation and Use of a Gum Solution, 5Dowfax3B2-0.75 Phenoxy-Phos/Citrate

A gum solution is produced in the same manner as Example 4, except that 1982.38 g of Dowfax 3B2 (Dow Chemical company, 45.4% by weight) is substituted for 1727.44 g of NAXAN 220, and the water addition is adjusted from 16031.00 g to 15776.06 g. The formulation is mixed by the same procedure as Example 4, and is introduced into both the developer and rinse stages of an ANTHEM Water Wash processor. An NP-1 plate is exposed at 14 W/135 rpm in an Eastman Kodak TRENDSETTER 3244 and developed in the processor using the gum solution of the present example. The processed plate is subsequently mounted on a printing press and utilized in a printing run of 40,000 impressions.

### Example 19

### Formulation and Use of a Gum Solution, 5 Naxan220-0.75 Benzyl Alcohol-Phos/Citrate

A gum solution is produced in the same manner as Example 4, except that 135 g of benzyl alcohol is substituted for 135 g of phenoxyethanol. The formulation is mixed according to the same procedure as in Example 4, and is introduced into both the developer and rinse stages of an ANTHEM Water Wash processor. An NP-1 plate is exposed at 14 W/135 rpm in an Eastman Kodak TRENDSETTER 3244 and developed in the processor using the gum solution of the present example. The processed plate is subsequently mounted on a printing press and utilized in a printing run of 40,000 impressions.

Although the present invention has been described with reference to specific details, it is not intended that such details should be regarded as limitations upon the scope of the invention, except as and to the extent that they are included in the accompanying claims.

What is claimed is:

1. A method of developing a printing member having a negative-working photopolymer imaging layer on an anodized aluminum substrate and which has been subjected to (i) a post-anodic sealing treatment of the substrate comprising exposure to an inorganic, phosphate and an inorganic fluoride, and (ii) imagewise exposure of the printing member to actinic imaging radiation, the method comprising the step of removing unimaged portions of the photopolymer by applying to the printing member a developer composition comprising water, a surfactant, and a polycarboxylic acid.

2. The method of claim 1 wherein the developer composition further comprises an organic, water-miscible cosolvent.

3. The method of claim 2 wherein the cosolvent is present at a level no greater than 5%.

4. The method of claim 2 wherein the cosolvent is at least one of benzyl alcohol, phenoxyethanol or propylene carbonate.

5. The method of claim 1 wherein the developer composition has a pH ranging from 7 to 8.5.

6. The method of claim 1 further comprising the step of rinsing the printing member following the applying step.

7. The method of claim 6 further comprising the step of applying a thin layer of the developer composition to the printing member following rinsing.

8. The method of claim 7 wherein the thin layer after drying has a deposited weight between 0.1 g/m² and 0.5 g/m².

9. The method of claim 1 wherein the polycarboxylic acid is citric acid.

10. The method of claim 1 wherein the polycarboxylic acid constitutes between between 0.05 and 1% of the composition by weight.

11. A method of printing with a printing member having a negative-working photopolymer imaging layer on an anodized aluminum substrate and which has been subjected to a post-anodic sealing treatment comprising exposure to an inorganic phosphate and an inorganic fluoride, the method comprising:
imagewise exposing the printing member to actinic imaging radiation; and
removing unimaged portions of the photopolymer by applying to the printing member a developer composition comprising water, a surfactant, and a polycarboxylic acid.

12. A developer composition suitable for developing printing members having a negative-working photopolymer imaging layer on an anodized aluminum substrate, the composition comprising:
water;
a surfactant;
a polycarboxylic acid; and
an organic, water-miscible cosolvent present at a level no greater than 5% by weight, wherein the co-solvent is at least one of benzyl alcohol, phenoxyethanol or propylene carbonate and the developer composition has a pH ranging from 7 to 8.5.

13. The composition of claim 12 wherein the surfactant is an anionic surfactant.

14. The composition of claim 13 wherein the anionic surfactant is a salt of an aryl sulfonic acid.

15. The composition of claim 13 wherein the anionic surfactant is present at a level ranging from 2.5% to 7.5% by volume.

16. The composition of claim 12 further comprising a defoaming agent.

17. The composition of claim 12 wherein the polycarboxylic acid is citric acid.

18. The composition of claim 12 wherein the polycarboxylic acid constitutes between 0.05 and 1% of the composition by weight.
